(19) United States
(12) Patent Application Publication
(10) Pub. No.: US 2026/0314186 A1
(43) Pub. Date: Oct. 8, 2026

(54) DISPLAY SUBSTRATE, MANUFACTURING METHOD AND DISPLAY DEVICE

(71) Applicants: Hefei BOE Joint Technology Co., Ltd., Hefei, Anhui (CN); BOE TECHNOLOGY GROUP CO., LTD., Beijing (CN); Beijing BOE Technology Development Co., Ltd., Beijing (CN)

(72) Inventor: Huifeng Wang, Beijing (CN)

(73) Assignees: Hefei BOE Joint Technology Co., Ltd., Hefei, Anhui (CN); BOE TECHNOLOGY GROUP CO., LTD., Beijing (CN); Beijing BOE Technology Development Co., Ltd., Beijing (CN)

(21) Appl. No.: 19/480,479

(22) PCT Filed: Mar. 6, 2025
(86) PCT No.: PCT/CN2025/080880

§ 371 Date: Oct. 31, 2025

(30) Foreign Application Priority Data
Apr. 22, 2024 (CN) 202410488960.0

(51) Int. Cl. H10K 59/122; H10K 59/12; H10K 71/13

(52) U.S. Cl. CPC H10K 59/122; H10K 59/1201; H10K 71/135

(57) ABSTRACT

A display substrate, a manufacturing method and a display device are provided. The display substrate includes a base substrate, a pixel definition layer and a plurality of light-emitting subpixels. The pixel definition layer defines a plurality of pixel aperture regions and a plurality of communication regions and at least part of pixel aperture regions adjacent to each other are in communication with each other via a corresponding communication region, the communication region includes a first channel region, a second channel region, and a middle channel region located between the first channel region and the second channel region, a width direction of an orthogonal projection of the communication region onto the base substrate is perpendicular to the extension direction of the channel, and a width of at least one of the first channel region and the second channel region is greater than a width of the middle channel region.

### CROSS-REFERENCE TO RELATED APPLICATION

This application claims a priority of the Chinese patent application No. 202410488960.0 filed on Apr. 22, 2024, which is incorporated herein by reference in its entirety.

### TECHNICAL FIELD

The present disclosure relates to the field of display technology, in particular to a display substrate, a manufacturing method and a display device.

### BACKGROUND

As compared with a conventional liquid crystal display device, an Organic Light Emission Diode (OLED) display device further includes such advantages as self-illumination, low power consumption, being free of a back light source, being free of any view angle limitation and rapid response, in addition to being thin and light, so it has a wide application prospect.

Film-forming methods of the OLED mainly includes vacuum evaporation and solution processing. The solution processing mainly includes inkjet printing, inkjet coating, spin coating and silk screen printing. The inkjet printing has relatively high material utilization and it may be used for the manufacture of a large-size product, so it becomes a principal method for the mass production of large-size OLED display devices. However, during the inkjet printing, there is such a phenomenon as non-uniform image.

### SUMMARY

An object of the present disclosure is to provide a display substrate, a manufacturing method and a display device, so as to improve the non-uniformity of the image.

The present disclosure provides the following technical solutions.

In a first aspect, the present disclosure provides in some embodiments a display substrate, including: a base substrate; and a pixel definition layer and a plurality of light-emitting subpixels located on the base substrate. The pixel definition layer defines a plurality of pixel aperture regions and a plurality of communication regions, the light-emitting subpixel in the plurality of light-emitting subpixels is located in a corresponding pixel aperture region in the plurality of pixel aperture regions, at least part of pixel aperture regions adjacent to each other are in communication with each other via a corresponding communication region in the plurality of communication regions, and the communication region is configured to serve as a channel through which printing ink for the light-emitting subpixel passes; the communication region includes a first side and a second side arranged opposite to each other in an extension direction of the channel, the channel of the communication region includes a first channel region located at the first side, a second channel region located at the second side, and a middle channel region located between the first channel region and the second channel region, a width direction of an orthogonal projection of the communication region onto the base substrate is perpendicular to the extension direction of the channel, and a width of at least one of the first channel region and the second channel region is greater than a width of the middle channel region.

Illustratively, the first channel region is in communication with one of corresponding two pixel aperture regions in the plurality of pixel aperture regions, and the second channel region is in communication with the other of the corresponding two pixel aperture regions; and a maximum width of the first channel region is less than or equal to a width of the pixel aperture region in communication with the first channel region, and a maximum width of the second channel region is less than or equal to a width of the pixel aperture region in communication with the second channel region.

Illustratively, a maximum width of the first channel region and/or a maximum width of the second channel region is greater than or equal to a first threshold, and the first threshold is a minimum allowable landing dot size of the printing ink.

Illustratively, the first threshold is 10 μm.

Illustratively, the width of the middle channel region is greater than 0 and less than or equal to 50 μm; and a length of the middle channel region in the extension direction of the channel is greater than or equal to 5 μm and less than or equal to 100 μm.

Illustratively, in a direction from the first side to the second side, the width of the first channel region decreases gradually, and the width of the second channel region increases gradually.

Illustratively, a pattern of an orthogonal projection of the first channel region onto the base substrate includes a first contour line extending in the direction from the first side to the second side, and the first contour line is an arc-like curve or an oblique straight line tilting relative to the extension direction of the channel, to cause the channel of the first channel region to be gradually expanded in the direction from the first side to the second side; and/or a pattern of an orthogonal projection of the second channel region onto the base substrate includes a second contour line extending in the direction from the first side to the second side, and the second contour line is an arc-like curve or an oblique straight line tilting relative to the extension direction of the channel, to cause the channel of the second channel region to be gradually converged in the direction from the first side to the second side.

Illustratively, the width of the middle channel region remains unchanged in the direction from the first side to the second side; or the width of the middle channel region decreases gradually and then increases gradually in the direction from the first side to the second side.

Illustratively, in a case that the width of the middle channel region decreases gradually and then increases gradually in the direction from the first side to the second side, the middle channel region includes a third contour line extending in the direction from the first side to the second side, and the third contour line is an arc-like curve formed through smoothly extending at least one of the first contour line and the second contour line, or an oblique straight line tilting relative to the extension direction of the channel.

Illustratively, the middle channel region includes a midpoint in the extension direction of the channel, a pattern of an orthogonal projection of the first channel region onto the base substrate is symmetric with a pattern of an orthogonal projection of the second channel region onto the base substrate with respect to a first axis of symmetry, and the first axis of symmetry passes through the midpoint and is perpendicular to the extension direction of the channel.

Illustratively, the pixel definition layer includes a plurality of first pixel banks and a plurality of second pixel banks, and extension directions of the plurality of first pixel banks intersect extension directions of the plurality of second pixel banks to jointly define the plurality of pixel aperture regions arranged in an array; the first pixel bank in the plurality of first pixel banks is configured to separate two adjacent pixel aperture regions from each other, and a height of the second pixel bank in the plurality of second pixel banks in a direction perpendicular to the base substrate is less than a height of the first pixel bank in the plurality of first pixel banks in the direction perpendicular to the base substrate, to cause the second pixel bank to form the channel of the communication region at a side distal to the base substrate.

Illustratively, the first pixel bank extends in a first direction, the second pixel bank extends in a second direction, and the first direction intersects the second direction; the light-emitting subpixels in a same color are arranged in the first direction, so that two adjacent columns of the pixel aperture regions in the first direction are in communication with each other via the communication region formed by the second pixel banks; and the light-emitting subpixels in different colors are arranged alternately in the second direction, to cause two adjacent rows of the pixel aperture regions in the second direction to be spaced apart from each other through the first pixel banks.

Illustratively, two adjacent rows of the light-emitting subpixels are arranged in a staggered manner, to cause the pixel aperture region in which the light-emitting subpixel in one row of the light-emitting subpixels in the two adjacent rows of the light-emitting subpixels is located to be directly opposite to the communication region between the light-emitting subpixels in the other row of the light-emitting subpixels in the second direction, a minimum width of the first pixel bank in the second direction in a region between the two adjacent rows of the light-emitting subpixels is greater than or equal to 7.5, and a maximum width of the first pixel bank in the region between the two adjacent rows of the light-emitting subpixels is less than or equal to 10.

In a second aspect, the present disclosure further provides in some embodiments a display device, including the above-mentioned display substrate.

In a third aspect, the present disclosure further provides in some embodiments a method for manufacturing the above-mentioned display substrate, including: providing a base substrate; and forming a pixel definition layer and a plurality of light-emitting subpixels on the base substrate. The pixel definition layer defines a plurality of pixel aperture regions and a plurality of communication regions, the light-emitting subpixel in the plurality of light-emitting subpixels is formed in a corresponding pixel aperture region in the plurality of pixel aperture regions through inkjet printing, at least part of pixel aperture regions adjacent to each other are in communication with each other via a corresponding communication region in the plurality of communication regions, and the communication region is configured to serve as a channel through which printing ink for the light-emitting subpixel passes; the communication region includes a first side and a second side arranged opposite to each other in an extension direction of the channel, the channel of the communication region includes a first channel region located at the first side, a second channel region located at the second side, and a middle channel region located between the first channel region and the second channel region, a width direction of an orthogonal projection of the communication region onto the base substrate is perpendicular to the extension direction of the channel, and a width of at least one of the first channel region and the second channel region is greater than a width of the middle channel region.

The present disclosure has the following beneficial effects.

In the embodiments of the present disclosure, the pixel definition layer of the display substrate defines the plurality of pixel aperture regions and the plurality of communication regions, the light-emitting subpixel is arranged in the pixel aperture region, the communication region is located between at least part of pixel aperture regions adjacent to each other, at least part of film layers of the light-emitting subpixel are formed through inkjet printing, and the communication region is configured to serve as the channel through which the printing ink for the light-emitting subpixel passes. The channel of the communication region is designed in such a manner that the width of at least one of the first channel region and the second channel region arranged opposite to each other in the extension direction of the channel is greater than the width of the middle channel region, i.e., the channel of the communication region close to the pixel aperture region is wide and the middle channel is narrow. Due to the narrow middle channel of the communication region, an aperture size of the pixel aperture region is increased as possible. Due to the wide channel of the communication region close to the pixel aperture region, it is able to prevent the flow of the printing ink from being interrupted in the channel, ensure the fluidity of ink droplets, and improve the uniformity of the ink droplets between different light-emitting subpixels, thereby to prevent the occurrence of any image defect.

### BRIEF DESCRIPTION OF THE DRAWINGS

FIG. 1 is a schematic view showing a display substrate according to some embodiments of the present disclosure;

FIG. 2 is a sectional view of the display substrate along line E-E′ in FIG. 1;

FIG. 3 is another schematic view showing the display substrate according to some embodiments of the present disclosure;

FIG. 4 is a partial schematic view showing the display substrate according to some embodiments of the present disclosure;

FIG. 5 is yet another schematic view showing the display substrate according to some embodiments of the present disclosure;

FIG. 6 is still yet another schematic view showing the display substrate according to some embodiments of the present disclosure;

FIG. 7 is still yet another schematic view showing the display substrate according to some embodiments of the present disclosure; and

FIG. 8 is still yet another schematic view showing the display substrate according to some embodiments of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

Before describing a display substrate, a manufacturing method and a display device provided in the embodiments of the present disclosure, the related art will be described hereinafter.

Film-forming methods of an OLED mainly includes vacuum evaporation and solution processing. The application of the vacuum evaporation to a small-size product is mature, and the vacuum evaporation has already been used in mass production. The solution processing mainly includes inkjet printing, inkjet coating, spin coating and silk screen printing. The inkjet printing has relatively high material utilization and it may be used for the manufacture of a large-size product, so it becomes a principal method for the mass production of large-size OLED display devices.

The inkjet printing is a method for forming a light-emitting layer of an OLED display device. To be specific, an OLED organic material is dissolved using a solvent, and then directly sprayed onto a surface of a display substrate to form the light-emitting layer. However, during the inkjet printing, there is such a phenomenon as non-uniform image.

It is found through researches that, one of the reasons for the non-uniform image during the inkjet printing is described as follows.

In the related art, a line bank is used to improve the light-emitting uniformity of a display device, i.e., consecutive two or more light-emitting subpixels in a same column or row (e.g., the light-emitting subpixels in a same column or row have a same color) are limited within one pixel bank. To be specific, a height of a portion of the pixel bank extending in a column direction of the light-emitting subpixels is greater than a thickness of a film layer of the light-emitting subpixel, and a height of a portion of the pixel bank between two light-emitting subpixels in a same color is less than the thickness of the film layer of the light-emitting subpixel. In this way, a communication region is formed between the light-emitting subpixels in a same color within one pixel bank, and the communication region is configured to serve as a channel through which printing ink for a pixel passes. The printing ink for the light-emitting subpixels in a same color flows in the channel and spreads evenly.

In order to meet the requirement on a high resolution of the display device, a pixel aperture ratio is reduced, so the channel of the communication region is designed to be relatively narrow. A width of the channel is less than a width of the light-emitting subpixel, so as to provide a space for the light-emitting subpixel as possible, thereby to increase the pixel aperture ratio. However, in a case that the width of the channel of the communication region is reduced to a certain extent, the flow of ink droplets of the printing ink in the channel may be interrupted, and the fluidity of the ink droplets may be limited, leading to a local non-uniform coalesced droplet volume, as well as non-uniform ink droplets between the pixels. Hence, such a defect as non-uniform image occurs.

In addition, the channel of the communication region is narrowed suddenly relative to an aperture of the light-emitting subpixel, a droplet allowable landing zone is reduced, and the ink droplet can only land in a zone where the light-emitting subpixel is located. Hence, the droplet landing accuracy is highly required in an arrangement direction of the light-emitting subpixels in a same color, and a risk of cross-color of the ink droplets between the adjacent light-emitting subpixels in different colors may increase.

An object of the present disclosure is to provide a display substrate, a manufacturing method and a display device, so as to improve the image quality.

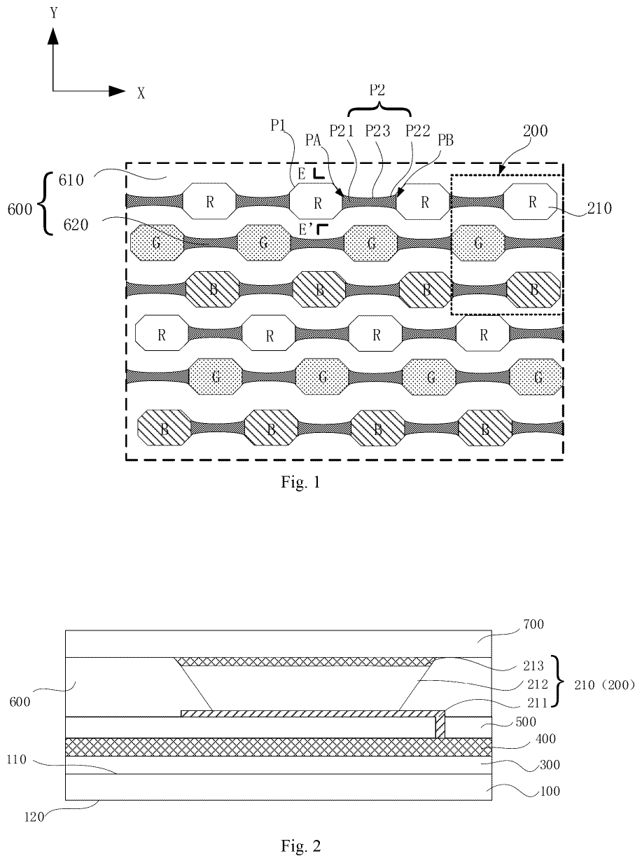

As shown in FIG. 1, the present disclosure provides in some embodiments a display substrate, which includes a base substrate 100 and a plurality of pixel units 200 located on the base substrate 100. The plurality of pixel units 200 is arranged in an array, each pixel unit 200 includes a plurality of light-emitting subpixels 210, and the light-emitting subpixel 210 is a light-emitting element which emits light in a single color.

In a case that the display substrate is used for displaying, the light-emitting subpixels 210 in different colors are controlled to emit light, and the light in different colors is mixed to achieve colorful display. In some embodiments of the present disclosure, each pixel unit 200 includes three light-emitting subpixels 210, i.e., a first subpixel R, a second subpixel G and a third subpixel B. The first subpixel R is a red (R) subpixel for emitting red light, the second subpixel G is a green (G) subpixel for emitting green light, and the third subpixel B is a blue subpixel for emitting blue light. However, the present disclosure is not limited thereto.

The display substrate provided in the embodiments of the present disclosure is, but not limited to, an OLED display substrate. FIG. 2 is a sectional view of the display substrate in FIG. 1 along line E-E′. As shown in FIG. 2, the display substrate includes the base substrate 100, a barrier layer 300, a pixel driving layer 400, a planarization layer 500, a pixel definition layer (PDL) 600, the light-emitting subpixels 210, and an encapsulation layer 700. The light-emitting subpixel 210 includes a first electrode 211, an organic light-emitting function layer 212 and a second electrode 213. The base substrate 100, the barrier layer 300, the pixel driving layer 400, the planarization layer 500, the first electrode 211 and the pixel definition layer 600 are collectively called as a display backplate.

In some embodiments of the present disclosure, the base substrate 100 is of a plate-like structure, and it includes a first surface 110 and a second surface 120 arranged opposite to each other. As viewed in FIG. 2, the first surface 110 is located above the second surface 120, and the barrier layer 300 is arranged on the first surface 110 of the base substrate 100. The barrier layer 300 is an inorganic insulation film layer, and it is made of an inorganic material, e.g., an oxide or nitride. The barrier layer 300 is of a single-layered or multiple-layered structure including the inorganic material. Due to characteristics of the inorganic material, the barrier layer 300 is used to isolate the base substrate 100 from structures above the base substrate 100, so as to reduce or prevent foreign matters, moisture or external air from entering the display substrate through the base substrate 100, and provide a flat surface.

As shown in FIG. 2, in some embodiments of the present disclosure, the pixel driving layer 400 is arranged at a side of the barrier layer 300 away from the base substrate 100, the pixel driving layer 400 includes thin film transistors and a pixel circuit, and the pixel circuit includes data lines and scanning line crossing the data lines. The thin film transistor is a top-gate transistor, a bottom-gate transistor or a double-gate transistor, and a specific type of the thin film transistor will not be particularly defined herein.

In some embodiments of the present disclosure, the planarization layer 500 is arranged at a side of the pixel driving layer 400 away from the barrier layer 300, and the planarization layer 500 covers the pixel driving layer 400. The planarization layer 500 is provided with a flat surface at a side away from the pixel driving layer 400, so as to facilitate the formation of the structures above the planarization layer 500. The planarization layer 500 is provided with an electrode aperture in communication with the pixel driving layer 400.

As shown in FIG. 2. in some embodiments of the present disclosure, the pixel definition layer 500 is arranged at a side of the planarization layer 500 away from the pixel driving layer 400, the pixel definition layer 600 defines a plurality of pixel aperture regions P1, and each light-emitting subpixel 210 is located in a corresponding pixel aperture region P1.

In some embodiments of the present disclosure, the first electrode 211 is arranged between the planarization layer 500 and the pixel definition layer 600 and faces the pixel aperture region P1, and the first electrode 211 is coupled to the pixel circuit in the pixel driving layer 400 via the electrode aperture. The organic light-emitting function layer 212 is arranged in the pixel aperture region P1 of the pixel definition layer 600. The second electrode 213 is arranged at a side of the organic light-emitting function layer 212 away from the first electrode 211, i.e., the organic light-emitting function layer 212 is arranged between the first electrode 211 and the second electrode 213.

In some embodiments of the present disclosure, the organic light-emitting function layer 212 includes an emitting layer (EML), and the subpixels in different colors have different organic light-emitting function layers 212. For example, the subpixel R includes a red light-emitting layer, the subpixel G includes a green light-emitting layer, and the subpixel B includes a blue light-emitting layer.

The organic light-emitting function layer 212 includes one or more of a Hole Injection Layer (HIL), a Hole Transport Layer (HTL), a Hole Block Layer (HBL), an Electron Block Layer (EBL), an Electron Injection Layer (EIL) and an Electron Transport Layer (ETL). In order to reduce a process difficulty and improve the yield, the hole injection layer, the hole transport layer, the hole block layer, the electron block layer, the electron injection layer and the electron transport layer may be shared by the light-emitting subpixels 210, i.e., they are designed as common layers.

As shown in FIG. 2, in some embodiments of the present disclosure, the display substrate further includes the encapsulation layer 700, and the encapsulation layer 700 covers the pixel units 200, so as to hermetically encapsulate the pixel units 200, prevent external moisture and oxygen from entering the organic light-emitting function layer 212, and protect the pixel units 200. Lid encapsulation or thin film encapsulation is used, and depending on different encapsulation types, the encapsulation layer 700 has different structures, which will not be particularly defined herein.

In some embodiments of the present disclosure, the first electrode 211 is an anode, and the second electrode 213 is a cathode. The anode is made of gold (Au), a transparent conductive polymer (e.g., PEDOT:PSS) and Indium Tin Oxide (ITO) conductive glass, and the cathode is made of aluminum (Al), lithium (Li), magnesium (Mg), calcium (Ca), indium (In), etc. The organic light-emitting function layer 212 between the anode and the cathode is formed through inkjet printing, and ink for the inkjet printing includes an OLED organic material and a solvent for dissolving the OLED organic material. For the inkjet printing, a pixel well, i.e., the pixel aperture region P1, needs to be formed in the pixel definition layer 600 in advance, so that ink droplets flow to a designated position accurately.

In some embodiments of the present disclosure, as shown in FIGS. 1 and 2, the pixel definition layer 600 further defines a plurality of communication regions P2, at least part of the adjacent pixel aperture regions P1 are in communication with each other via the communication region P2. The communication region P2 is configured to serve as a channel through which printing ink for the light-emitting subpixel 210 passes.

For example, the pixel aperture regions P1 corresponding to the adjacent light-emitting subpixels 210 in a same color are in communication with each other via the communication region P2, so that the printing ink for the light-emitting subpixels 210 in a same color flows through the channel formed by the communication region P2 to spread more evenly.

In some embodiments of the present disclosure, as shown in FIGS. 1, 3 and 4, the communication region P2 includes a first side PA and a second side PB arranged opposite to each other in an extension direction of the channel. The channel of the communication region P2 includes a first channel region P21 at the first side PA, a second channel region P22 at the second side PB, and a middle channel region P23 between the first channel region P21 and the second channel region P22. A width direction of an orthogonal projection of the communication region P2 onto the base substrate 100 (i.e., direction Y in FIG. 1) is perpendicular to the extension direction of the channel, and a width of at least one of the first channel region P21 and the second channel region P22 (D1/D2) is greater than a width D3 of the middle channel region P23.

In the embodiments of the present disclosure, at least part of film layers (e.g., the light-emitting function layer) of the light-emitting subpixel 210 are formed through inkjet printing, and the communication region P2 is configured to serve as the channel through which the printing ink for the light-emitting subpixel 210 passes. The channel of the communication region P2 is designed in such a manner that the width of at least one of the first channel region P21 and the second channel region P22 arranged opposite to each other in the extension direction of the channel is greater than the width of the middle channel region P23, i.e., the channel of the communication region P2 close to the pixel aperture region P1 is wide and the middle channel is narrow. Due to the narrow middle channel of the communication region P2, an aperture size of the pixel aperture region P1 is increased as possible. Due to the wide channel of the communication region P2 close to the pixel aperture region P1, it is able to prevent the flow of the printing ink from being interrupted in the channel, ensure the fluidity of ink droplets, and improve the uniformity of the ink droplets between different light-emitting subpixels 210, thereby to prevent the occurrence of any image defect.

In addition, as shown in FIG. 4, the channel of the communication region P2 close to the pixel aperture region P1 is wide, an allowable landing position of an ink droplet E includes, in addition to the pixel aperture region P1, a position of the communication region P2 close to the pixel aperture region P1, so it is able to increase an allowable landing space for the ink droplets E, reduce the requirement on the droplet landing accuracy of the ink droplets E in an arrangement direction of the light-emitting subpixels 210 in a same color, and reduce a risk of cross-color of the ink droplets E.

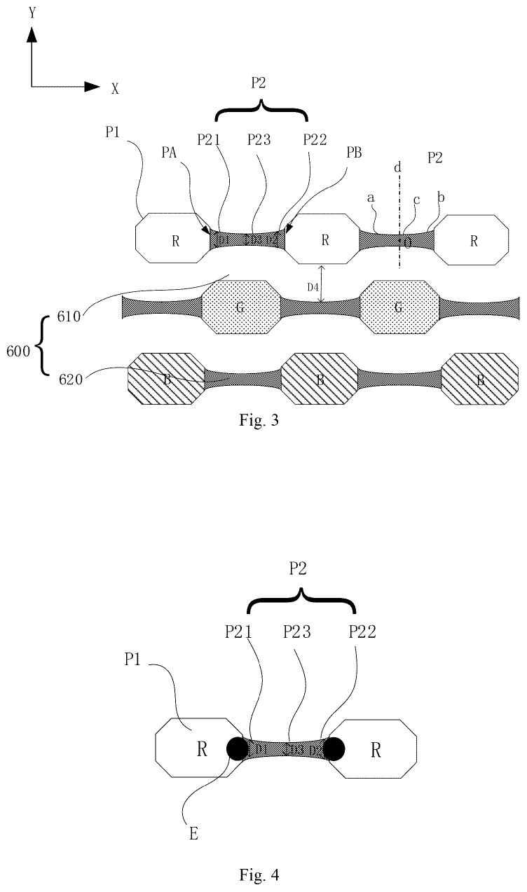

In some illustrative embodiments of the present disclosure, as shown in FIG. 3, the first channel region P21 is in communication with one of corresponding two pixel aperture regions P1 in the plurality of pixel aperture regions P1, and the second channel region P22 is in communication with the other of the corresponding two pixel aperture regions P1; and a maximum width of the first channel region P21 is less than or equal to a width of the pixel aperture region P1 in communication with the first channel region P21, and a maximum width of the second channel region P22 is less than or equal to a width of the pixel aperture region P1 in communication with the second channel region P22. Based on the above, the maximum width of the communication region P2 is not greater than the width of the pixel aperture region P1, so it is able to increase a pixel aperture ratio as possible while increasing the width of the channel.

In some illustrative embodiments of the present disclosure, as shown in FIG. 4, the maximum width of the first channel region P21 and/or the maximum width of the second channel region P22 is greater than or equal to a first threshold, and the first threshold is a minimum allowable landing dot size of the printing ink. In this way, the first channel region P21 provides an allowable landing space for the ink droplets E of the printing ink, so as to reduce the requirement on the landing accuracy of the ink droplets E. For example, the first threshold is 10 μm. However, the present disclosure is not limited thereto. In some other embodiments of the present disclosure, the maximum width of the first channel region P21 may also be less than the first threshold.

In addition, in some illustrative embodiments of the present disclosure, the width D3 of the middle channel region P23 is greater than 0 and less than or equal to 50 μm. Further, the width D3 of the middle channel region P23 is 5 μm to 10 μm. A length L of the middle channel region P23 in the extension direction of the channel is greater than or equal to 5 μm and less than or equal to 100 μm. In this way, it is able to reduce an occupation space of the communication region P2, and provide more space for the pixel aperture region P1, thereby to increase the pixel aperture ration. However, the present disclosure is not limited thereto, and in actual use, the width and the length of the middle channel region P23 may be designed appropriately according to the requirements on an actual product, e.g., the pixel aperture ratio.

In addition, in some illustrative embodiments of the present disclosure, as shown in FIG. 3, in a direction from the first side PA to the second side PB, the width D1 of the first channel region P21 decreases gradually, and the width D2 of the second channel region P22 increases gradually. In other words, in the direction from the first side PA to the second side PB, the width of the entire channel of the communication region P2 decreases gradually and then increases gradually, so as to be of a dumbbell-like shape. A portion of the channel with a maximum width is proximate to the pixel aperture region P1, and a portion of the channel with a minimum width is the middle channel region P23. Through the structure with two wide ends and a narrow middle portion, it is able to increase the fluidity of the ink droplets E, and prevent the flow of the ink droplets E from being interrupted.

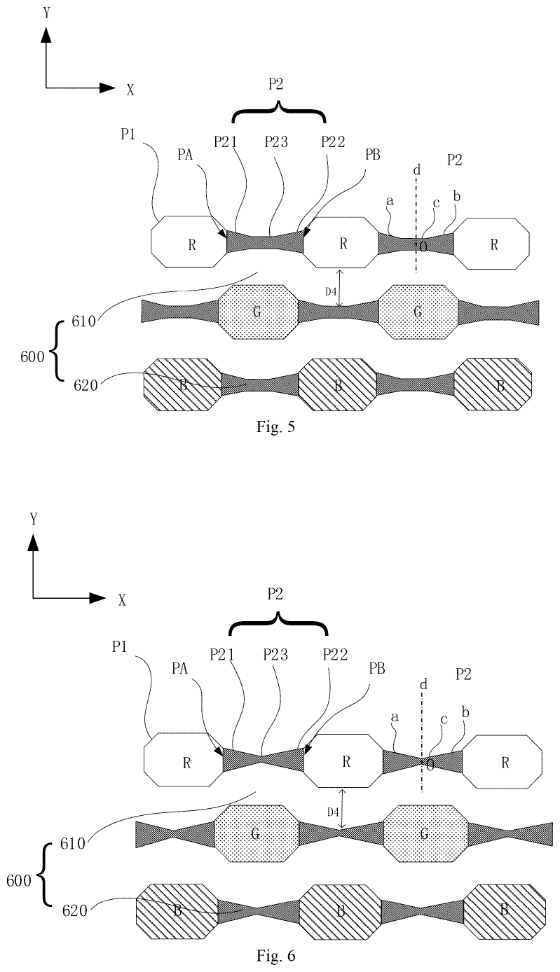

It should be appreciated that, the above is merely for illustrative purposes, and the present disclosure is not limited thereto. For example, in some other embodiments of the present disclosure, as shown in FIG. 5, in the direction from the first side PA to the second side PB, the first channel region P21 is wider than the middle channel region P23, and the width of the first channel region P21 remains unchanged, rather than decreases gradually. In the direction from the first side PA to the second side PB, the second channel region P22 is wider than the middle channel region P23, and the width of the first channel region P21 remains unchanged, rather than decreases gradually.

In some illustrative embodiments of the present disclosure, as shown in FIGS. 3 and 5, a pattern of an orthogonal projection of the first channel region P21 onto the base substrate 100 includes a first contour line a extending in the direction from the first side PA to the second side PB, and the first contour line a is an arc-like curve or an oblique straight line tilting relative to the extension direction of the channel, so that the channel of the first channel region P21 is gradually expanded in the direction from the first side PA to the second side PB; and/or a pattern of an orthogonal projection of the second channel region P22 onto the base substrate 100 includes a second contour line b extending in the direction from the first side PA to the second side PB, and the second contour line b is an arc-like curve or an oblique straight line tilting relative to the extension direction of the channel, so that the channel of the second channel region P22 is gradually converged in the direction from the first side PA to the second side PB.

In some illustrative embodiments of the present disclosure, as shown in FIG. 5, the width of the middle channel region P23 remains unchanged in the direction from the first side PA to the second side PB. For example, as shown in FIG. 5, a pattern of an orthogonal projection of the middle channel region P23 onto the base substrate 100 is of a rectangular shape.

In some other illustrative embodiments of the present disclosure, as shown in FIGS. 4, 6 and 7, the width of the middle channel region P23 decreases gradually and then increases gradually in the direction from the first side PA to the second side PB.

In some illustrative embodiments of the present disclosure, in a case that the width of the middle channel region P23 decreases gradually and then increases gradually in the direction from the first side PA to the second side PB, the middle channel region P23 includes a third contour line c extending in the direction from the first side PA to the second side PB, and the third contour line c is an arc-like curve formed through smoothly extending at least one of the first contour line a and the second contour line b, or an oblique straight line tilting relative to the extension direction of the channel.

To be specific, as shown in FIG. 4, in some embodiments of the present disclosure, the first contour line a is an arc-like curve, the second contour line b is an arc-like curve, and the middle channel region P23 remains unchanged in the direction from the first side PA to the second side PB. At this time, in the direction from the first side PA to the second side PB, the channel of the communication region P2 is converged gradually at first, then remains unchanged in the middle channel region P23, and then expanded gradually. Due to the gradual, slow transition between the widths of the channel of the first channel region P21 and the second channel region P22, the ink flows conveniently in the channel. Further, for example, each of the first channel region P21 and the second channel region P22 has a minimum width at a side close to the middle channel region P23, and the minimum width is equal to the width of the middle channel region P23. However, the present disclosure is not limited thereto.

As shown in FIG. 3, in some embodiments of the present disclosure, the first contour line a is an arc-like curve, the second contour line b is an arc-like curve, and the third contour line c is an arc-like curve formed through smoothly extending at least one of the first contour line a and the second contour line b. At this time, in the direction from the first side PA to the second side PB, the channel of the first channel region P21 is gradually converged, and the width of the middle channel region P23 decreases gradually and then increases gradually, and the channel of the second channel region P22 is gradually expanded. At this time, in the direction from the first side PA to the second side PB, the channel of the communication region P2 is gradually converged at first, then remains unchanged in the middle channel region P23, and then is gradually expanded. Due to the gradual, slow transition between the widths of the channel of the first channel region P21 and the second channel region P22, the ink flows conveniently in the channel. Further, each of the first channel region P21 and the second channel region P22 has a minimum width at a side close to the middle channel region P23, the middle channel region P23 has a maximum width at two sides close to the first channel region P21 and the second channel region P22, and the minimum width of each of the first channel region P21 and the second channel region P22 is equal to the maximum width of the middle channel region P23. However, the present disclosure is not limited thereto.

In addition, as shown in FIG. 5, in some other embodiments of the present disclosure, the first contour line a is an oblique straight line tilting relative to the extension direction of the channel, and the second contour line b is an oblique straight line tilting relative to the extension direction of the channel. At this time, a pattern of the orthogonal projection of each of the first channel region P21 and the second channel region P22 onto the base substrate 100 is a trapezoid, e.g., isosceles trapezoid or any other trapezoidal shape. In the direction from the first side PA to the second side PB, the middle channel region P23 remains unchanged. At this time, in the direction from the first side PA to the second side PB, the channel of the communication region P2 is gradually converged at first, then remains unchanged in the middle channel region P23, and then is expanded gradually. Due to the gradual, slow transition between the widths of the channel of the first channel region P21 and the second channel region P22, the ink flows conveniently in the channel. Further, each of the first channel region P21 and the second channel region P22 has a minimum width at a side proximate to the middle channel region P23, and the minimum width is equal to the width of the middle channel region P23. However, the present disclosure is not limited thereto.

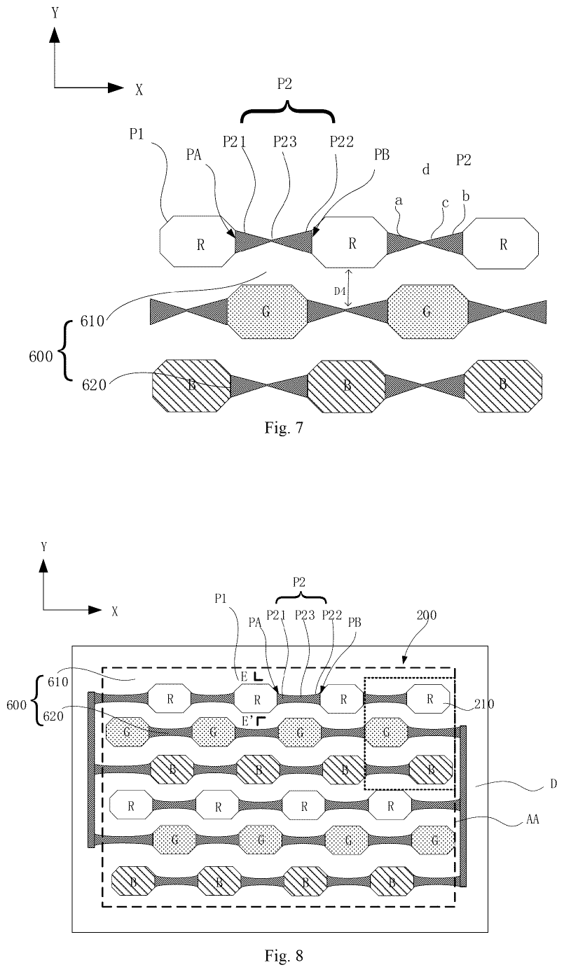

In addition, as shown in FIG. 7, in some other embodiments of the present disclosure, the first contour line a is an oblique straight line tilting relative to the extension direction of the channel, and the second contour line b is an oblique straight line tilting relative to the extension direction of the channel. At this time, a pattern of the orthogonal projection of each of the first channel region P21 and the second channel region P22 onto the base substrate 100 is a triangle, e.g., isosceles triangle or any other triangular shape. In the direction from the first side PA to the second side PB, the middle channel region P23 remains unchanged. At this time, in the direction from the first side PA to the second side PB, the channel of the communication region P2 is gradually converged at first, then remains unchanged in the middle channel region P23, and then is expanded gradually. Due to the gradual, slow transition between the widths of the channel of the first channel region P21 and the second channel region P22, the ink flows conveniently in the channel. Further, each of the first channel region P21 and the second channel region P22 has a minimum width at a side proximate to the middle channel region P23, and the minimum width is equal to the width of the middle channel region P23. The width of the middle channel region P23 approaches to 0. However, the present disclosure is not limited thereto.

In addition, as shown in FIG. 6, in some other embodiments of the present disclosure, the first contour line a is an oblique straight line tilting relative to the extension direction of the channel, the second contour line b is an oblique straight line tilting relative to the extension direction of the channel, and the third contour line c is an oblique straight line formed through smoothly extending at least one of the first contour line a and the second contour line b. At this time, a pattern of the orthogonal projection of the communication region P2 onto the base substrate 100 includes two trapezoids with upper bases abut against each other. At this time, in the direction from the first side PA to the second side PB, the channel of the communication region P2 is gradually converged at first, and then is expanded gradually. Due to the gradual, slow transition between the widths of the channel of the first channel region P21 and the second channel region P22, the ink flows conveniently in the channel. Further, each of the first channel region P21 and the second channel region P22 has a minimum width at a side proximate to the middle channel region P23, and the minimum width is equal to the width of the middle channel region P23. The width of the middle channel region P23 approaches to 0. However, the present disclosure is not limited thereto.

The shapes of the channel of the communication region p2 have been illustratively described hereinabove, but the present disclosure is not limited thereto.

In addition, in some illustrative embodiments of the present disclosure, as shown in FIG. 3, the middle channel region P23 includes a midpoint O in the extension direction of the channel, a pattern of an orthogonal projection of the first channel region P21 onto the base substrate 100 is symmetric with a pattern of an orthogonal projection of the second channel region P22 onto the base substrate 100 with respect to a first axis of symmetry d, and the first axis of symmetry d passes through the midpoint O and is perpendicular to the extension direction of the channel. However, the present disclosure is not limited thereto. In actual use, the shape of the first channel region P21 may be asymmetric with the shape of the second channel region P22.

In addition, in some illustrative embodiments of the present disclosure, as shown in FIG. 3, the pixel definition layer 600 includes a plurality of first pixel banks 610 and a plurality of second pixel banks 620, and extension directions of the plurality of first pixel banks 610 intersect extension directions of the plurality of second pixel banks 620 to jointly define the plurality of pixel aperture regions P1 arranged in an array; the first pixel bank 610 is configured to separate two adjacent pixel aperture regions P1 from each other, and a height of the second pixel bank 620 in a direction perpendicular to the base substrate 100 is less than a height of the first pixel bank 610 in the direction perpendicular to the base substrate 100, so that the second pixel bank 620 forms the channel of the communication region P2 at a side away from the base substrate 100.

In some illustrative embodiments of the present disclosure, as shown in FIGS. 1 and 3, the plurality of pixel units 200 is arranged in rows in a second direction Y and in columns in a first direction X, i.e., the plurality of pixel units 200 includes a plurality of pixel rows in the first direction X spaced apart from each other evenly, and a plurality of pixel columns in the second direction Y spaced apart from each other evenly. The first direction X is perpendicular to the second direction Y, and the pixel units 200 in the plurality of pixel rows are aligned in the second direction Y to form the pixel columns. In other words, the first direction X is a row direction of the pixel array, and the second direction Y is a column direction of the pixel array.

The first pixel bank 610 extends in the first direction X, the second pixel bank 620 extends in the second direction Y, and the first direction X intersects the second direction Y; the light-emitting subpixels 210 in a same color are arranged in the first direction X, so that two adjacent columns of the pixel aperture regions P1 in the first direction X are in communication with each other via the communication region P2 formed by the second pixel banks 620; and the light-emitting subpixels 210 in different colors are arranged alternately in the second direction Y, so that two adjacent rows of the pixel aperture regions P1 in the second direction Y are spaced apart from each other through the first pixel banks 610.

Each pixel unit 200 includes a plurality of light-emitting subpixels 210. For example, each pixel unit 200 includes a first subpixel R, a second subpixel G and a third subpixel B. The first subpixel R is a subpixel for emitting red light, the second subpixel G is a subpixel for emitting green light, and the third subpixel B is a subpixel for emitting blue light. The pixel definition layer 600 includes a plurality of communication regions P corresponding to the light-emitting subpixels 210 in different colors in the pixel unit 200.

It should be appreciated that, the above is merely for illustrative purposes, and in some other embodiments of the present disclosure, the light-emitting subpixels 210 in a same color may also be arranged in a staggered manner. At this time, the light-emitting subpixels 210 in a same color adjacent to each other in different rows or different columns are in communication with each other through the communication region P2.

In addition, in some embodiments of the present disclosure, all the pixel units 200 in a display region of the display substrate are arranged in rows and columns, and the light-emitting subpixels 210 in a same color in a same row or a same column are in communication with each other through the communication region P2. In some other embodiments of the present disclosure, the light-emitting subpixels in a same color in a same row or a same column are divided into a plurality of groups, the light-emitting subpixels 210 in each group are in communication with each other through the communication region P2, and different groups of light-emitting subpixels 210 are spaced apart from each other.

In addition, in some illustrative embodiments of the present disclosure, as shown in FIG. 8, the display substrate includes a display region AA and a peripheral region D surrounding the display region AA. In the display region AA, the light-emitting subpixels 210 in a same color in a same row or a same column are in communication with each other through the communication region P2, and the light-emitting subpixels 210 in a same color in adjacent rows or columns are further in communication with each other through the communication region P2 at the peripheral region D.

In some illustrative embodiments of the present disclosure, as shown in FIG. 3, two adjacent rows of the light-emitting subpixels 210 are arranged in a staggered manner, so that the pixel aperture region P1 in which the light-emitting subpixel 210 in one row of the light-emitting subpixels 210 is located directly faces the communication region P2 between the light-emitting subpixels 210 in the other row of the light-emitting subpixels 210 in the second direction Y, a minimum width of the first pixel bank 610 in the second direction Y in a region between the two adjacent rows of the light-emitting subpixels 210 is greater than or equal to 7.5, and a maximum width of the first pixel bank 610 is less than or equal to 10. In this way, it is able to provide a sufficiently large spacing between the communication region P2 and the light-emitting subpixels 210 in different colors which are located adjacent to, but are not in communication with, the communication region P2 while preventing the flow of the ink droplets E from being interrupted in the channel, thereby to prevent the occurrence of cross-color between the pixels.

The present disclosure further provides in some embodiments a display device, which includes the above-mentioned display substrate. The embodiments of the display device include any of the above-mentioned embodiments of the display substrate or a combination thereof. The display device is a product having an image display function, e.g., display, television, advertising board, digital photo frame, laser printer having a display function, telephone, mobile phone, Personal Digital Assistant (PDA), digital camera, camcorder, viewfinder, navigator, vehicle, large-size wall, home appliances, or information query equipment (e.g., service query devices and monitors for e-government affairs, banks, hospitals, or electric power department).

The display device includes the display substrate in any one of the above-mentioned embodiments, and it has the same beneficial effects of the display substrate, which will not be particularly defined herein.

The present disclosure further provides in some embodiments a method for manufacturing the above-mentioned display substrate, which includes: Step S01 of providing a base substrate 100; and forming a pixel definition layer 600 and a plurality of light-emitting subpixels 210 on the base substrate 100. The pixel definition layer 600 defines a plurality of pixel aperture regions P1 and a plurality of communication regions P2, the light-emitting subpixel 210 in the plurality of light-emitting subpixels 210 is formed in a corresponding pixel aperture region P1 in the plurality of pixel aperture regions P1 through inkjet printing, at least part of pixel aperture regions P1 adjacent to each other are in communication with each other via a corresponding communication region P2 in the plurality of communication regions P2, and the communication region P2 is configured to serve as a channel through which printing ink for the light-emitting subpixel 210 passes; the communication region P2 includes a first side PA and a second side PB arranged opposite to each other in an extension direction of the channel, the channel of the communication region P2 includes a first channel region P21 located at the first side PA, a second channel region P22 located at the second side PB, and a middle channel region P23 located between the first channel region P21 and the second channel region P22, a width direction of an orthogonal projection of the communication region P2 onto the base substrate 100 is perpendicular to the extension direction of the channel, and a width of at least one of the first channel region P21 and the second channel region P22 is greater than a width of the middle channel region P23.

The method is used to manufacture the display substrate in any one of the above-mentioned embodiments, and it has the same beneficial effects of the display substrate, which will not be particularly defined herein.

Some description will be given as follows.
(1) The drawings merely relate to structures involved in the embodiments of the present disclosure, and the other structures may refer to those known in the art.
(2) For clarification, in the drawings for describing the embodiments of the present disclosure, a thickness of a layer or region is zoomed out or in, i.e., these drawings are not provided according to an actual scale. It should be appreciated that, in the case that such an element as layer, film, region or substrate is arranged “on” or “under” another element, it may be directly arranged “on” or “under” the other element, or an intermediate element may be arranged therebetween.
(3) In a case of no conflict, the embodiments of the present disclosure and the features therein may be combined to obtain new embodiments.

The above embodiments are merely the preferred embodiments of the present disclosure, but shall not be construed as limiting the scope of the present disclosure. The scope of the present disclosure shall be subject to the scope defined by the appended claims.

1. A display substrate, comprising:
a base substrate; and
a pixel definition layer and a plurality of light-emitting subpixels located on the base substrate, wherein the pixel definition layer defines a plurality of pixel aperture regions and a plurality of communication regions, the light-emitting subpixel in the plurality of light-emitting subpixels is located in a corresponding pixel aperture region in the plurality of pixel aperture regions, at least part of pixel aperture regions adjacent to each other are in communication with each other via a corresponding communication region in the plurality of communication regions, and the communication region is configured to serve as a channel through which printing ink for the light-emitting subpixel passes; wherein
the communication region comprises a first side and a second side arranged opposite to each other in an extension direction of the channel, the channel of the communication region comprises a first channel region located at the first side, a second channel region located at the second side, and a middle channel region located between the first channel region and the second channel region, a width direction of an orthogonal projection of the communication region onto the base substrate is perpendicular to the extension direction of the channel, and a width of at least one of the first channel region and the second channel region is greater than a width of the middle channel region.

2. The display substrate according to claim 1, wherein the first channel region is in communication with one of corresponding two pixel aperture regions in the plurality of pixel aperture regions, and the second channel region is in communication with the other of the corresponding two pixel aperture regions; and a maximum width of the first channel region is less than or equal to a width of the pixel aperture region in communication with the first channel region, and a maximum width of the second channel region is less than or equal to a width of the pixel aperture region in communication with the second channel region.

3. The display substrate according to claim 1, wherein a maximum width of the first channel region and/or a maximum width of the second channel region is greater than or equal to a first threshold, and the first threshold is a minimum allowable landing dot size of the printing ink.

4. The display substrate according to claim 3, wherein the first threshold is 10 μm.

5. The display substrate according to claim 1, wherein the width of the middle channel region is greater than 0 and less than or equal to 50 μm; and a length of the middle channel region in the extension direction of the channel is greater than or equal to 5 μm and less than or equal to 100 μm.

6. The display substrate according to claim 1, wherein in a direction from the first side to the second side, the width of the first channel region decreases gradually, and the width of the second channel region increases gradually.

7. The display substrate according to claim 6, wherein a pattern of an orthogonal projection of the first channel region onto the base substrate comprises a first contour line extending in the direction from the first side to the second side, and the first contour line is an arc-like curve or an oblique straight line tilting relative to the extension direction of the channel, to cause the channel of the first channel region to be gradually expanded in the direction from the first side to the second side; and/or
a pattern of an orthogonal projection of the second channel region onto the base substrate comprises a second contour line extending in the direction from the first side to the second side, and the second contour line is an arc-like curve or an oblique straight line tilting relative to the extension direction of the channel, to cause the channel of the second channel region to be gradually converged in the direction from the first side to the second side.

8. The display substrate according to claim 7, wherein the width of the middle channel region remains unchanged in the direction from the first side to the second side; or the width of the middle channel region decreases gradually and then increases gradually in the direction from the first side to the second side.

9. The display substrate according to claim 8, wherein in a case that the width of the middle channel region decreases gradually and then increases gradually in the direction from the first side to the second side, the middle channel region comprises a third contour line extending in the direction from the first side to the second side, and the third contour line is an arc-like curve formed through smoothly extending at least one of the first contour line and the second contour line, or an oblique straight line tilting relative to the extension direction of the channel.

10. The display substrate according to claim 1, wherein the middle channel region comprises a midpoint in the extension direction of the channel, a pattern of an orthogonal projection of the first channel region onto the base substrate is symmetric with a pattern of an orthogonal projection of the second channel region onto the base substrate with respect to a first axis of symmetry, and the first axis of symmetry passes through the midpoint and is perpendicular to the extension direction of the channel.

11. The display substrate according to claim 1, wherein the pixel definition layer comprises a plurality of first pixel banks and a plurality of second pixel banks, and extension directions of the plurality of first pixel banks intersect extension directions of the plurality of second pixel banks to jointly define the plurality of pixel aperture regions arranged in an array; the first pixel bank in the plurality of first pixel banks is configured to separate two adjacent pixel aperture regions from each other, and a height of the second pixel bank in the plurality of second pixel banks in a direction perpendicular to the base substrate is less than a height of the first pixel bank in the plurality of first pixel banks in the direction perpendicular to the base substrate, to cause the second pixel bank to form the channel of the communication region at a side distal to the base substrate.

12. The display substrate according to claim 11, wherein the first pixel bank extends in a first direction, the second pixel bank extends in a second direction, and the first direction intersects the second direction; the light-emitting subpixels in a same color are arranged in the first direction, so that two adjacent columns of the pixel aperture regions in the first direction are in communication with each other via the communication region formed by the second pixel banks; and the light-emitting subpixels in different colors are arranged alternately in the second direction, to cause two adjacent rows of the pixel aperture regions in the second direction to be spaced apart from each other through the first pixel banks.

13. The display substrate according to claim 12, wherein two adjacent rows of the light-emitting subpixels are arranged in a staggered manner, to cause the pixel aperture region in which the light-emitting subpixel in one row of the light-emitting subpixels in the two adjacent rows of the light-emitting subpixels is located to be directly opposite to the communication region between the light-emitting subpixels in the other row of the light-emitting subpixels in the second direction, wherein a minimum width of the first pixel bank in the second direction in a region between the two adjacent rows of the light-emitting subpixels is greater than or equal to 7.5 μm, and a maximum width of the first pixel bank in the region between the two adjacent rows of the light-emitting subpixels is less than or equal to 10 μm.

14. A display device, comprising the display substrate according to claim 1.

15. A method for manufacturing the display substrate according to claim 1, comprising:
providing a base substrate; and
forming a pixel definition layer and a plurality of light-emitting subpixels on the base substrate, wherein the pixel definition layer defines a plurality of pixel aperture regions and a plurality of communication regions, the light-emitting subpixel in the plurality of light-emitting subpixels is formed in a corresponding pixel aperture region in the plurality of pixel aperture regions through inkjet printing, at least part of pixel aperture regions adjacent to each other are in communication with each other via a corresponding communication region in the plurality of communication regions, and the communication region is configured to serve as a channel through which printing ink for the light-emitting subpixel passes; wherein the communication region comprises a first side and a second side arranged opposite to each other in an extension direction of the channel, the channel of the communication region comprises a first channel region located at the first side, a second channel region located at the second side, and a middle channel region located between the first channel region and the second channel region, a width direction of an orthogonal projection of the communication region onto the base substrate is perpendicular to the extension direction of the channel, and a width of at least one of the first channel region and the second channel region is greater than a width of the middle channel region.

16. The display device according to claim 14, wherein the first channel region is in communication with one of corresponding two pixel aperture regions in the plurality of pixel aperture regions, and the second channel region is in communication with the other of the corresponding two pixel aperture regions; and a maximum width of the first channel region is less than or equal to a width of the pixel aperture region in communication with the first channel region, and a maximum width of the second channel region is less than or equal to a width of the pixel aperture region in communication with the second channel region.

17. The display device according to claim 14, wherein a maximum width of the first channel region and/or a maximum width of the second channel region is greater than or equal to a first threshold, and the first threshold is a minimum allowable landing dot size of the printing ink.

18. The display device according to claim 17, wherein the first threshold is 10 μm.

19. The display device according to claim 14, wherein the width of the middle channel region is greater than 0 and less than or equal to 50 μm; and a length of the middle channel region in the extension direction of the channel is greater than or equal to 5 μm and less than or equal to 100 μm.

20. The display device according to claim 14, wherein in a direction from the first side to the second side, the width of the first channel region decreases gradually, and the width of the second channel region increases gradually.
